(19) United States
(12) Patent Application Publication
(10) Pub. No.: US 2012/0154704 A1
(43) Pub. Date: Jun. 21, 2012

(54) PHOTOSENSOR, SEMICONDUCTOR DEVICE, AND LIQUID CRYSTAL PANEL

(75) Inventors: Makoto Nakazawa, Osaka-shi (JP); Tomohiro Kimura, Osaka-shi (JP)

(73) Assignee: SHARP KABUSHIKI KAISHA, Osaka-shi, Osaka (JP)

(21) Appl. No.: 13/392,292

(22) PCT Filed: Jul. 16, 2010
(86) PCT No.: PCT/JP2010/062060

§ 371 Date: Feb. 24, 2012

(30) Foreign Application Priority Data
Aug. 25, 2009 (JP) 2009-194077

(51) Int. Cl. G02F 1/136; H01L 27/146

(52) U.S. Cl. 349/43; 257/53; 257/E27.13

(57) ABSTRACT

The light use efficiency of a thin film diode is improved even when the semiconductor layer of the diode has a small thickness, thereby improving the light detection sensitivity of the diode. A thin film diode (130) having a first semiconductor layer (131) including, at least, an n-type region (131n) and a p-type region (131p) is provided on one side of a substrate (101), and a silicon layer (171) is provided between the substrate and the first semiconductor layer, facing the first semiconductor layer. Asperities are formed on the side of the silicon layer facing the first semiconductor layer, and asperities are provided on the side of the first semiconductor layer facing the silicon layer and the side thereof opposite the side facing the silicon layer.

### REFERENCE TO RELATED APPLICATIONS

This application is the national stage under 35 USC 371 of International Application No. PCT/JP2010/062060, filed Jul. 16, 2010, which claims priority from Japanese Patent Application No. 2009-194077, filed Aug. 25, 2009, the entire contents of which are incorporated herein by reference.

### FIELD OF THE INVENTION

The present invention relates to a photosensor that includes a thin film diode (TFD) having a semiconductor layer including, at least, an n-type region and a p-type region. Further, the present invention relates to a semiconductor device including a thin film diode and a thin film transistor (TFT). Furthermore, the present invention relates to a liquid crystal panel including such a semiconductor device.

### BACKGROUND OF THE INVENTION

Touch sensor functionality can be established by incorporating a photosensor including a thin film diode into a display device. In such a display device, information can be input as a finger or a touch pen touches the viewer's side (i.e. the display surface) of the display device and the resulting change in light entering the display surface is detected by a photosensor.

In such a display device, a change in light resulting from a finger touching the display surface may be small depending on the environment, such as the ambient brightness. As such, a change in light may not be detected by a photosensor.

JP2008-287061A discloses a technique for improving the light detection sensitivity of a photosensor in a semiconductor device used in a liquid crystal display device. The technique will now be described referring to FIG. 14.

This semiconductor device includes, on a substrate (active matrix substrate) 910, insulating layers 941, 942, 943 and 944 formed in this order, a thin film diode 920 and a thin film transistor 930. The thin film diode 920 is a PIN diode having a semiconductor layer 921 composed of an n-type region 921n, a p-type region 921p and a low resistance region 921i. The thin film transistor 930 includes a semiconductor layer 931 composed of a channel region 931c, an n-type region 931a as the source region, and an n-type region 931b as the drain region. A gate electrode 932 is provided above the channel region 931c with an insulating layer 943 interposed therebetween. The n-type region 931b is connected with a pixel electrode (not shown).

The thin film diode 920 receives light entering the display surface (the top of paper in FIG. 14). A light-blocking layer 990 is provided between the thin film diode 920 and the substrate 910 to prevent light from the backlight (not shown) on the side of the substrate 910 opposite the display surface (the bottom of paper in FIG. 14) from entering the thin film diode 920. The light-blocking layer 990 extends along the surface of a recess 992, which is formed by removing a portion of the insulating layer 941. The recess 992 is tapered, becoming wider toward the top, to form a slope 991 of the light-blocking layer 990 extending along the slope of the recess 992.

The light-blocking layer 990 also serves as a reflective layer. Accordingly, light traveling through the display surface that did not enter the thin film diode 920 but entered the area between the thin film diode 920 and the light-blocking layer 990 is reflected from the light-blocking layer 990 and enters the thin film diode 920. The slope 991 of the light-blocking layer 990 reflects light incident on the slope 991 back to the thin film diode 920.

In the semiconductor device shown in FIG. 14, the light-blocking layer 990 described above causes more light that entered the display surface to enter the thin film diode 920. Thus, light detection sensitivity is improved.

### SUMMARY OF THE INVENTION

However, even the semiconductor device shown in FIG. 14 does not provide sufficient light detection sensitivity. The reasons will be discussed below.

The semiconductor layer 921 of the thin film diode 920 is formed at the same time as the semiconductor layer 931 of the thin film transistor 930. Thus, the semiconductor layer 921 has a very small thickness. Consequently, part of light that entered the semiconductor layer 921 is not absorbed by the semiconductor layer 921 and passes through. As such, even though light entering the area between the thin film diode 920 and the light-blocking layer 990 is reflected from the slope 991 back toward the semiconductor layer 921, part of light reflected toward the semiconductor layer 921 may not be absorbed by the semiconductor layer 921 and may pass through the semiconductor layer 921. Moreover, the slope 991 is only provided near the edge of the light-blocking layer 990. Thus, most of the light reflected from the slope 991 enters the periphery of the thin film diode 920. As a result, only a small amount of light enters the low resistance region 921i, which constitutes the light receiving region.

An object of the present invention is to solve this problem with the conventional art by improving light use efficiency and thus improving the light detection sensitivity of the thin film diode even when the semiconductor layer of the thin film diode has a small thickness.

The photosensor of the present invention includes: a substrate; and a thin film diode provided close to one side of the substrate and having a first semiconductor layer including, at least, an n-type region and a p-type region. It also includes a silicon layer provided between the substrate and the first semiconductor layer. Asperities are provided on a side of the silicon layer facing the first semiconductor layer. Asperities are provided on a side of the first semiconductor layer facing the silicon layer and a side thereof opposite the side facing the silicon layer.

According to the present invention, asperities are provided on the side of the silicon layer facing the first semiconductor layer, such that light that entered the silicon layer is emitted from the silicon layer in different directions. As a result, light from different directions enters the first semiconductor layer. Since asperities are provided on both sides of the first semiconductor layer in the thickness direction, light that entered the first semiconductor layer travels a longer distance inside the first semiconductor layer. As a result, more light is absorbed in the first semiconductor layer. Accordingly, light use efficiency and thus light detection sensitivity will be improved even with a first semiconductor layer with a small thickness.

### BRIEF DESCRIPTION OF THE DRAWINGS

FIG. 1 is a schematic cross sectional view of a semiconductor device according to Embodiment 1 of the present invention.

FIG. 2 explains how the light detection sensitivity of the thin film diode is improved in the semiconductor device according to Embodiment 1 of the present invention.

FIG. 3A is a cross sectional view of the semiconductor device according to Embodiment 1 of the present invention, illustrating one manufacturing step thereof.

FIG. 3B is a cross sectional view of the semiconductor device according to Embodiment 1 of the present invention, illustrating one manufacturing step thereof.

FIG. 3C is a cross sectional view of the semiconductor device according to Embodiment 1 of the present invention, illustrating one manufacturing step thereof.

FIG. 3D is a cross sectional view of the semiconductor device according to Embodiment 1 of the present invention, illustrating one manufacturing step thereof.

FIG. 3E is a cross sectional view of the semiconductor device according to Embodiment 1 of the present invention, illustrating one manufacturing step thereof.

FIG. 3F is a cross sectional view of the semiconductor device according to Embodiment 1 of the present invention, illustrating one manufacturing step thereof.

FIG. 3G is a cross sectional view of the semiconductor device according to Embodiment 1 of the present invention, illustrating one manufacturing step thereof.

FIG. 3H is a cross sectional view of the semiconductor device according to Embodiment 1 of the present invention, illustrating one manufacturing step thereof.

FIG. 3I is a cross sectional view of the semiconductor device according to Embodiment 1 of the present invention, illustrating one manufacturing step thereof.

FIG. 3J is a cross sectional view of the semiconductor device according to Embodiment 1 of the present invention, illustrating one manufacturing step thereof.

FIG. 3K is a cross sectional view of the semiconductor device according to Embodiment 1 of the present invention, illustrating one manufacturing step thereof.

FIG. 3L is a cross sectional view of the semiconductor device according to Embodiment 1 of the present invention, illustrating one manufacturing step thereof.

FIG. 4 is a schematic cross sectional view of a semiconductor device according to Embodiment 2 of the present invention.

FIG. 5 is a cross sectional view of major parts of a TFT array substrate of a liquid crystal panel according to Embodiment 2 of the present invention, where one electrode of an electrostatic capacitance and a common electrode line connected thereto are formed of a polycrystalline silicon layer.

FIG. 6 is a cross sectional view of major parts of a TFT array substrate of a liquid crystal panel according to Embodiment 2 of the present invention, where one electrode of an electrostatic capacitance and a common electrode line connected thereto are formed of a metal layer.

FIG. 7 is a schematic cross sectional view of a semiconductor device according to Embodiment 3 of the present invention.

FIG. 8 is a graph illustrating changes in the light absorption coefficient of polycrystalline silicon and that of amorphous silicon relative to the wavelength.

FIG. 9 is a cross sectional view of major parts of a TFT array substrate of a liquid crystal panel including a semiconductor device according to Embodiment 4 of the present invention.

FIG. 10 is a cross sectional view of major parts of a TFT array substrate of a liquid crystal panel including another semiconductor device according to Embodiment 4 of the present invention.

FIG. 11 is a schematic cross sectional view of a liquid crystal display device including a liquid crystal panel according to Embodiment 5 of the present invention.

FIG. 12 is an equivalent circuit of one pixel of the liquid crystal panel according to Embodiment 5 of the present invention.

FIG. 13 is a perspective view of major parts of another liquid crystal display device according to Embodiment 5 of the present invention.

FIG. 14 is a cross sectional view of a conventional semiconductor device including a thin film diode and a thin film transistor.

### DETAILED DESCRIPTION OF THE INVENTION

A photosensor according to an embodiment of the present invention includes: a substrate; a thin film diode provided close to one side of the substrate and having a first semiconductor layer including, at least, an n-type region and a p-type region; and a silicon layer provided between the substrate and the first semiconductor layer, wherein asperities are provided on a side of the silicon layer facing the first semiconductor layer, and asperities are provided on a side of the first semiconductor layer facing the silicon layer and a side thereof opposite the side facing the silicon layer (first arrangement).

In the first arrangement, asperities are provided on the side of the silicon layer facing the first semiconductor layer. Thus, light that passes through the side of the silicon layer facing the first semiconductor layer can travel in differing directions. Preferably, the asperities are irregular and random ones. Since light can travel in different directions, the incident angle dependence of light detection sensitivity of the thin film diode may be reduced.

Asperities are provided on the side of the first semiconductor layer facing the silicon layer and the side thereof opposite the side facing the silicon layer. As asperities are provided on both sides thereof, light that entered the first semiconductor layer may travel a longer distance inside the first semiconductor layer irrespective of the direction of travel of the light.

In the first arrangement above, it is preferable that the silicon layer is made of polycrystalline silicon; and the asperities formed on the silicon layer include ridges formed on crystal grain boundaries of silicon (second arrangement). Thus, asperities may be formed on the surface of the silicon layer in a simple manner.

In the first or second arrangement above, it is preferable that the side of the first semiconductor layer opposite the silicon layer side has a surface roughness that is larger than that of the side of the silicon layer facing the first semiconductor layer (third arrangement). Thus, light may travel an even longer distance inside the first semiconductor layer. As a result, light detection sensitivity may further be improved.

In any one of the first to third arrangements above, it is preferable that a light-blocking layer provided between the substrate and the silicon silicon layer toward the substrate may be reflected from the light-blocking layer is included (fourth arrangement). Thus, light that traveled from the layer back toward the first semiconductor layer. As a result, light detection sensitivity may be improved. Further, when detection of light that passed through the substrate from the side of the substrate opposite the side with the first semiconductor layer is not desired, the light may be prevented from entering the first semiconductor layer.

In any one of the first to fourth arrangements above, at least an n-type region and a p-type region may be formed in the silicon layer, the n-type region and the p-type region of the silicon layer being electrically connected with the n-type region and the p-type region, respectively, of the first semiconductor layer (fifth arrangement). In the fifth arrangement, a thin film diode may be formed in the silicon layer. As a result, light detection sensitivity may further be improved without increasing the area of the substrate occupied by thin film diodes.

In any one of the first to fifth arrangements above, one of the first semiconductor layer and the silicon layer may be made of amorphous silicon and the other one of the first semiconductor layer and the silicon layer may be made of polycrystalline silicon (sixth arrangement). Particularly, when combined with the fifth arrangement, this arrangement includes a thin film diode made of amorphous silicon and a thin film diode made of polycrystalline silicon. As a result, a photosensor with improved light detection sensitivity irrespective of the wavelength of light may be realized.

A semiconductor device according to an embodiment of the present invention includes: the photosensor according to an embodiment of the present invention as described above; and a thin film transistor provided close to the same side of the substrate as the thin film diode, wherein the thin film transistor includes: a second semiconductor layer including a channel region, a source region and a drain region; a gate electrode that controls a conductivity of the channel region; and a gate insulating film provided between the second semiconductor layer and the gate electrode (seventh arrangement). Since the thin film diode and the thin film transistor are provided on a common substrate, the semiconductor device according to an embodiment of the present invention can be employed in various applications where light detection functionality is required.

In the seventh arrangement above, it is preferable that the first semiconductor layer and the second semiconductor layer are formed on a single insulating layer (eighth arrangement). Thus, the first and second semiconductor layers may be formed concurrently in a single process. As a result, the manufacturing process may be simplified.

In the seventh or eighth arrangement above, it is preferable that a side of the second semiconductor layer facing the substrate is flat (ninth arrangement). Thus, the light detection sensitivity of the thin film diode may be improved without adversely affecting the gate capability or the like of the thin film transistor. The side of the second semiconductor layer facing the substrate does not have to be completely flat but, suitably, it is substantially flat.

In any one of the seventh to ninth arrangements above, it is preferable that the first semiconductor layer has a thickness that is identical with that of the second semiconductor layer (tenth arrangement). Thus, the first and second semiconductor layers may be formed concurrently in a single process. As a result, the manufacturing process may be simplified. The first semiconductor layer and the second semiconductor layer do not have to be completely identical in thickness but, suitably, they are substantially identical.

A liquid crystal panel according to an embodiment of the present invention includes: the semiconductor device according to an embodiment of the present invention as described above; a counter substrate facing the side of the substrate where the thin film diode and the thin film transistor are provided; and a liquid crystal layer enclosed between the substrate and the counter substrate (eleventh arrangement). Thus, a liquid crystal panel with touch sensor functionality or ambient sensor functionality for measuring the ambient brightness may be realized.

In the eleventh arrangement above, it is preferable that the thin film transistor is a transistor for driving liquid crystal; the drain region is connected with a pixel electrode that works together with a common electrode on the counter substrate to apply a voltage to the liquid crystal layer and one electrode of an electrostatic capacitance provided to stabilize the voltage applied to the liquid crystal layer; the other electrode of the electrostatic capacitance and a line connected with the other electrode are formed in an n-type or p-type polycrystalline silicon thin film; and the polycrystalline silicon thin film and the polycrystalline silicon layer are formed on a single base layer provided on the substrate (twelfth arrangement). Thus, the aperture ratio of the liquid crystal panel may be improved without significantly altering the manufacturing process of the liquid crystal panel.

Now, the present invention will be described in detail based on several preferred embodiments. Of course, the present invention is not limited to the embodiments below. For purposes of explanation, the drawings referred to in the following description only show, in a simplified form, those components of the embodiments of the present invention that are relevant to the description of the present invention. Accordingly, the present invention may include any desired component(s) not shown in the drawings. Further, the sizes of the components in the drawings do not exactly reflect the sizes of the actual components and the size ratios of the components.

### Embodiment 1

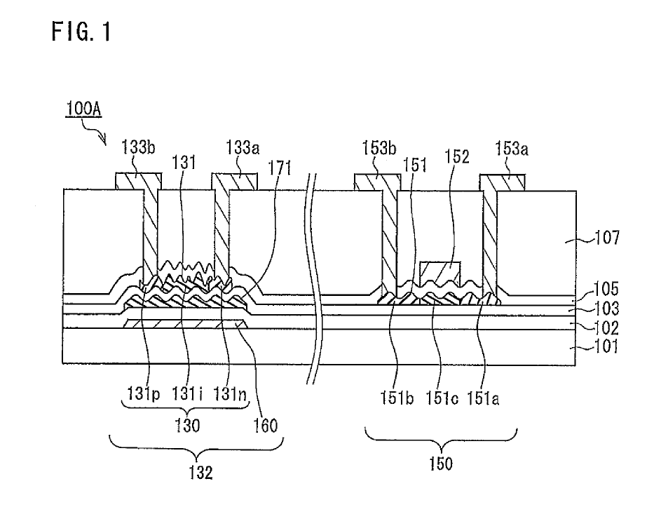

FIG. 1 is a schematic cross sectional view of a semiconductor device 100A according to Embodiment 1 of the present invention. The semiconductor device 100A includes: a photosensor 132 having a substrate 101, a thin film diode 130 formed above the substrate 101 with interposed base layers 102 and 103 therebetween as insulating layers, a polycrystalline silicon layer (silicon layer) 171 provided between the substrate 101 and the thin film diode 130, and a light-blocking layer 160 provided between the substrate 101 and the polycrystalline silicon layer 171; and a thin film transistor 150. The substrate 101 is preferably translucent. To simplify the drawing, FIG. 1 only shows a single photosensor 132 and a single thin film transistor 150; however, a plurality of photosensors 132 and a plurality of thin film transistors 150 may be formed on a common substrate. Further, to facilitate understanding, FIG. 1 shows a cross section of the photosensor 132 and that of the thin film transistor 150 in the same drawing; however, these cross sections do not have to be on a single common plane.

The thin film diode 130 has a semiconductor layer (first semiconductor layer) 131 including, at least, an n-type region 131n and a p-type region 131p. In the present embodiment, an intrinsic region 131i is provided between the n-type region 131n and the p-type region 131p in the semiconductor layer 131. Electrodes 133a and 133b are connected with the n-type region 131n and the p-type region 131p, respectively.

The thin film transistor 150 includes: a semiconductor layer (second semiconductor layer) 151 including a channel region 151c, a source region 151a and a drain region 151b; a gate electrode 152 for controlling the conductivity of the channel region 151c; and a gate insulating film 105 provided between the semiconductor layer 151 and the gate electrode 152. Electrodes 153a and 153b are connected with the source region 151a and the drain region 151b, respectively. The gate insulating film 105 expands over the semiconductor layer 131, too.

The semiconductor layer 131 of the thin film diode 130 and the semiconductor layer 151 of the thin film transistor 150 may have different crystallinities or the same crystallinity. If the semiconductor layers 131 and 151 have the same crystallinity, the crystal conditions of the semiconductor layers 131 and 151 do not have to be controlled separately. Thus, a reliable and high-performance semiconductor device 100A can be provided without complicating the manufacturing process.

An interlayer insulating film 107 is formed on the thin film diode 130 and the thin film transistor 150.

A polycrystalline silicon layer 171 is formed between the substrate 101 and the semiconductor layer 131. More particularly, the polycrystalline silicon layer 171 is located on the base layer 102 and faces the semiconductor layer 131.

A light-blocking layer 160 is provided between the substrate 101 and the polycrystalline silicon layer 171. More particularly, the light-blocking layer 160 is located on the substrate 101 facing the semiconductor layer 131. This prevents light that entered the side of the substrate 101 opposite that with the thin film diode 130 and passed the substrate 101 from entering the semiconductor layer 131.

Small and random asperities are provided on the side of the polycrystalline silicon layer 171 facing the semiconductor layer 131 (upper surface). Further, small and random asperities are provided on the side of the semiconductor layer 131 of the thin film diode 130 facing the polycrystalline silicon 171 (lower surface) and the side of the semiconductor layer 131 opposite that facing the polycrystalline silicon layer 171 (upper surface).

The asperities on the upper surface of the polycrystalline silicon layer 171 may be formed by using ridges that are formed on crystal grain boundaries when an amorphous silicon layer is crystallized, for example. More particularly, a laser beam is directed to an amorphous silicon layer such that the amorphous silicon layer melts before being solidified. During solidification, crystal cores are first developed, and solidification occurs beginning with these crystal cores. At this point, volume differs between the melted state and the solid state and thus crystal grain boundaries, which are solidified last, are raised like mountain ranges, or more-than-triple points where three or more crystals form boundaries (i.e. multiple points) are raised like mountains. In the context of the present invention, such a portion raised like a mountain range or a mountain on the surface of a silicon layer crystallized during the crystallization of the amorphous silicon layer is referred to as a “ridge”. The apexes of asperities are formed of such ridges. The manufacturing process is simplified by forming asperities on the upper surface of the polycrystalline silicon layer 171 at the same time as the polycrystalline silicon layer 171 is formed. The size of asperities formed on the upper surface of the polycrystalline silicon layer 171 (for example, surface roughness) may be controlled by controlling the degree to which the amorphous silicon layer is crystallized.

The formation of asperities on the lower surface of the semiconductor layer 131 of the thin film diode 130 is preferably caused by the asperities formed on the upper surface of the polycrystalline silicon layer 171 provided below the thin film diode 130. Thus, asperities may be formed on the lower surface of the semiconductor layer 131 without a dedicated step. As a result, the manufacturing process is simplified.

The formation of asperities on the upper surface of the semiconductor layer 131 of the thin film diode 130 is preferably caused, similar to the asperities on the lower surface of the thin film diode 130, by the asperities formed on the upper surface of the polycrystalline silicon layer 171. It should be noted that the formation of asperities on the upper surface of the semiconductor layer 131 of the thin film diode 130 is not limited to methods using asperities on the upper surface of the polycrystalline silicon layer 171. For example, in a method similar to that of forming asperities on the upper surface of the polycrystalline silicon layer 171, the formation of asperities may be caused by ridges formed on the surface of the semiconductor layer 131 while an amorphous silicon layer is crystallized to form the semiconductor layer 131. Thus, on the upper surface of the semiconductor layer 131, the asperities caused by the asperities on the upper surface of the polycrystalline silicon layer 171 are superimposed by the asperities caused by ridges formed on the surface of the semiconductor layer 131 while an amorphous silicon layer is crystallized to form the semiconductor layer 131. In other words, asperities that are different from those on the upper surface of the polycrystalline silicon layer 171 or those on the lower surface of the semiconductor layer 131 can be formed in a simple manner. According to this method, the surface roughness of the upper surface of the semiconductor layer 131 is generally larger than the surface roughness of the upper surface of the polycrystalline silicon layer 171 or the surface roughness of the lower surface of the semiconductor layer 131 (i.e. the surface roughness of the upper surface of the base layer 103). Specifically, the surface roughness Ra of the upper surface of the polycrystalline silicon layer 171 and the surface roughness Ra of the lower surface of the semiconductor layer 131 (i.e. the surface roughness of the upper surface of the base layer 103) are preferably in the range of 4 to 12 nanometers, and the surface roughness Ra of the upper surface of the semiconductor layer 131 is preferably in the range of 6 to 20 nanometers. The surface roughness Ra may be measured using an AFM (atomic force microscope), for example.

It should be noted that, in order to form asperities on a surface during a semiconductor manufacturing process, methods of forming asperities in a predetermined pattern using photolithography are generally known, and the present invention does not exclude asperities formed using photolithography. However, if photolithography is used, the lower limit of asperity pitch is around 2 micrometers, and asperity patterns are relatively regular. On the other hand, according to the above method which uses ridges formed during crystallization of semiconductor (silicon), an asperity pitch of 1 micrometer or less can be achieved by controlling crystallinity and, in addition, random asperities can be formed. Moreover, such a manufacturing process is simpler than photolithography.

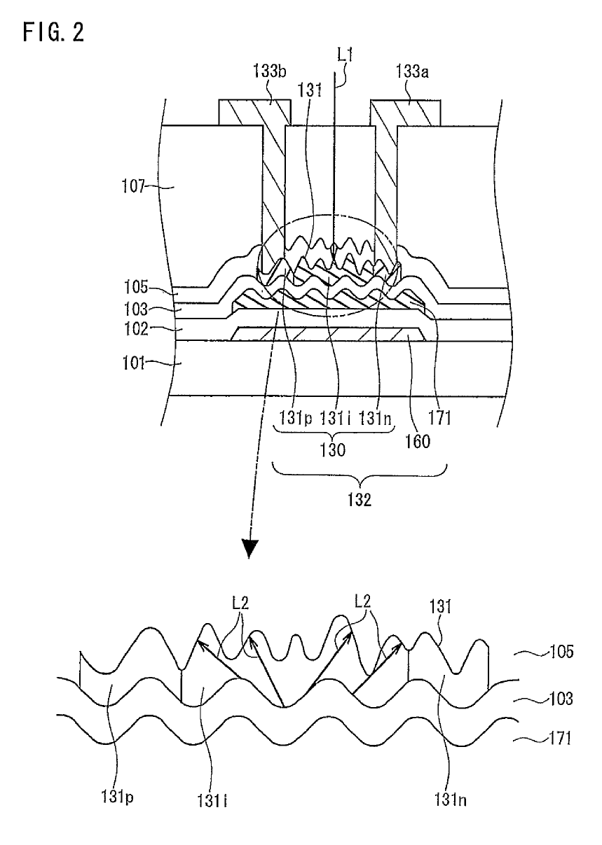

Effects of asperities formed on the upper surface of the polycrystalline silicon layer 171 and the upper and lower surfaces of the semiconductor layer 131 constituting the thin film diode 130 will now be described referring to FIG. 2. Incident light, L1, enters the thin film diode 130 from above. The incident light L1 enters the semiconductor layer 131 of the thin film diode 130 and is, ideally, absorbed by the semiconductor layer 131. However, since the semiconductor layer 131 has a small thickness, a portion of the incident light L1 passes through the semiconductor layer 131. The portion of light L1 that has passed through the semiconductor layer 131 passes the base layer 103, the polycrystalline silicon layer 171 and the base layer 102 in this order, reaches the upper surface of the light-blocking layer 160 and is reflected back from it, now called reflected light L2. The reflected light L2 passes the base layer 102, the polycrystalline silicon layer 171 and the base layer 103 in this order and travels toward the semiconductor layer 131. It should be noted, in this context, that the polycrystalline silicon layer 171 with asperities is disposed between the semiconductor layer 131 and the light-blocking layer 160. Thus, when the incident light L1 and the reflected light L2 pass through the asperities formed on the polycrystalline silicon layer 171, the direction of travel of the incident light L1 and the reflected light L2 is varied. Accordingly, reflected light L2 beams traveling in various directions enter the semiconductor layer 131. These reflected light L2 beams that form relatively large angles with respect to the normal line of the substrate 101 generally enter the semiconductor layer 131 in relatively large incident angles. Thus, the incident light L2 tends to travel a longer distance inside the semiconductor layer 131. In addition, asperities are formed on the upper and lower surfaces of the semiconductor layer 131. Thus, even those incident light L1 and reflected light L2 beams that form relatively small angles with respect to the normal line of the substrate 101 tend to travel a longer distance inside the semiconductor layer 131 than in an implementation where the upper and lower surfaces of the semiconductor layer 131 are flat. Thus, in a photosensor 132 according to an embodiment of the present invention, the incident light L1 and the reflected light L2 travel a longer distance inside the semiconductor layer 131. Consequently, more light is absorbed in the semiconductor layer 131. As a result, light use efficiency is improved and thus the light detection sensitivity of the thin film diode 130 is improved. Further, the more random the asperities on the upper surface of the polycrystalline silicon layer 171 and the asperities on the upper and lower surfaces of the semiconductor layer 131 are, the smaller incident angle dependence and thus the more stable improvement in light detection sensitivity can be achieved.

Preferably, the asperities on the upper surface of the polycrystalline silicon layer 171 cover the entire upper surface of the polycrystalline silicon layer 171. Thus, the light detection sensitivity of the thin film diode 130 is improved irrespective of the entrance location of the incident light L1 and the reflected light L2 on the polycrystalline silicon layer 171. Further, the area where asperities are formed is not limited. As a result, the step of forming asperities is simplified.

Suitably, the random asperities on the upper and lower surfaces of the semiconductor layer 131 of the thin film diode 130 cover at least the intrinsic region 131i; however, it is preferable that they cover the entire area including the n-type region 131n and the p-type region 131p. The manufacturing process is thus simplified.

In a semiconductor device 100A according to Embodiment 1 of the present invention, the light detection sensitivity of the photosensor 132 (thin film diode 130) is improved even if the semiconductor layer 131 is so thin that most of the incident light L1 passes through the semiconductor layer 131. For example, even if the semiconductor layer 131 has a thickness that is smaller than the difference in height between the apexes and bottoms of the asperities on the lower surface of the semiconductor layer 131, the reflected light L2 travels a longer distance inside the semiconductor layer 131, as shown in FIG. 2. As a result, the light detection sensitivity of the photosensor 132 (thin film diode 130) is improved. Accordingly, it is not necessary to increase the thickness of the semiconductor layer 131 to reduce the amount of light passing through the semiconductor layer 131. As a result, the semiconductor layer 131 may be formed in the same process as the semiconductor layer 151 of the thin film transistor 150, as will be discussed below.

One example of a method of manufacturing such a semiconductor device 100A of the present embodiment will be described. However, methods of manufacturing a semiconductor device 100A are not limited to the example below.

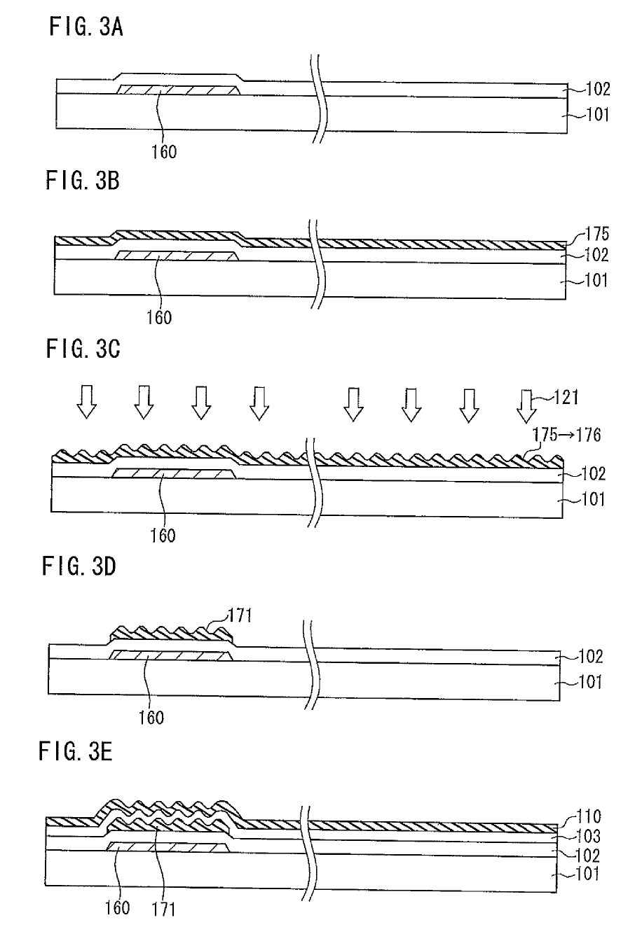

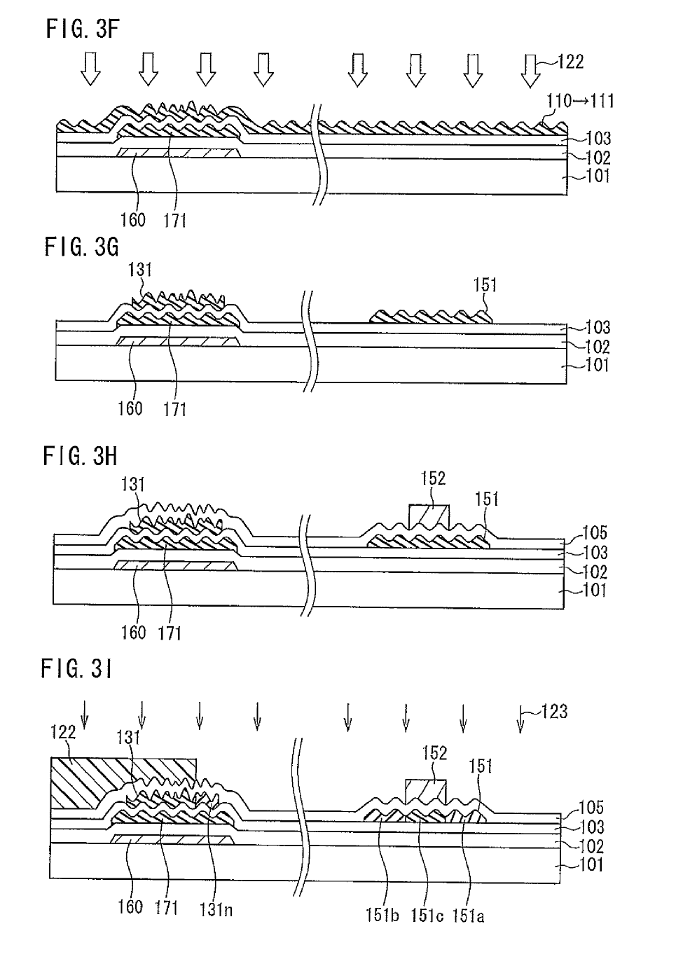

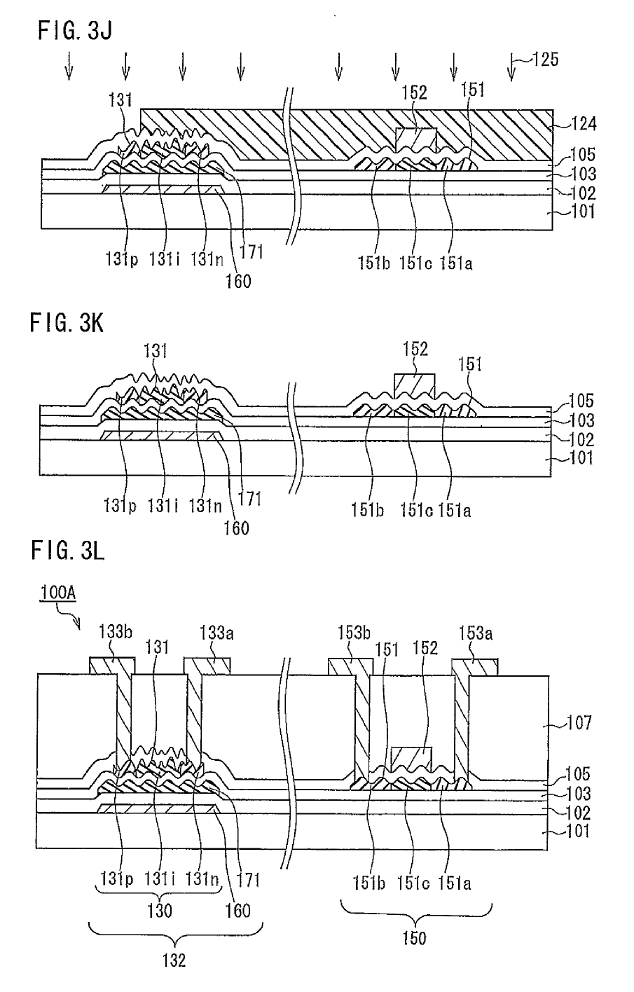

First, as shown in FIG. 3A, a light-blocking layer 160 and a base layer 102 are formed in this order on a substrate 101.

The substrate 101 is not limited to a particular type and can be selected as appropriate according to the application of the semiconductor device 100A or other conditions. For example, a translucent glass substrate (such as a low-alkali glass substrate) or quartz substrate may be used. If the substrate 101 is a low-alkali glass substrate, the substrate 101 may be thermally treated in advance at a temperature about 10 to 20° C. lower than the glass strain point.

The light-blocking layer 160 may be formed by photolithographically patterning a thin film formed over the substrate 101.

The thin film that is to be the light-blocking layer 160 may be made of a metal material, for example. Particularly, high-melting-point metals such as tantalum (Ta), tungsten (W) and molybdenum (Mo) are preferable when thermal treatments in later manufacturing steps are taken into consideration. A film of such a metal material is formed over the substrate 101 using sputtering. The thickness of the film is preferably in the range of about 100 to 300 nanometers.

Next, a pattern of a desired light-blocking layer 160 is formed on the upper surface of the film using a resist. Then, unnecessary portions of the film are removed using wet etching or dry etching. The portions of the film where a thin film diode 130 is to be formed later are left out. The portions of the film outside the area for the thin film diode 130, including the area(s) where a thin film transistor 150 is to be formed later, are removed. As a result, a patterned light-blocking layer 160 is provided.

Thereafter, a base layer 102 is formed to cover the substrate 101 and the light-blocking layer 160.

The base layer 102 is provided to prevent impurities from diffusing from the substrate 101. The base layer 102 may be made of, for example, a simple layer made of silicon oxide (SiO₂), a multiple layer made of a silicon nitride (SiNₓ or SiNO) film and a silicon oxide (SiO₂) film in this order from the substrate 101, or other known compositions. Such a base layer 102 may be formed using plasma CVD, for example. The thickness of the base layer 102 is preferably in the range of 100 to 600 nanometers, more preferably in the range of 150 to 450 nanometers.

Next, as shown in FIG. 3B, an amorphous semiconductor film 175 is formed over the base layer 102. Preferable semiconductors that may constitute the amorphous semiconductor film 175 include silicon. Other semiconductors such as Ge, SiGe, compound semiconductors, or chalcogenide may also be used. The following description uses silicon. The amorphous silicon film 175 is formed using a known technique, such as plasma CVD or sputtering. The thickness of the amorphous silicon film 175 is not limited to a particular value; however, it is preferably in the range of 50 to 100 nanometers. For example, an amorphous silicon film 175 with a thickness of 50 nanometers may be formed using plasma CVD. If the base layer 102 and the amorphous silicon film 175 are formed using the same film-formation method, these two layers may be formed consecutively.

Next, as shown in FIG. 3C, a laser beam 121 is directed to the amorphous silicon film 175 from above to crystallize the amorphous silicon film 175. The laser beam 121 may be an XeCl excimer laser beam (with a wavelength of 308 nanometers and a pulse width of 40 nanoseconds) or a KrF excimer laser beam (with a wavelength of 248 nanometers). The laser beam 121 is adjusted to illuminate an area of an elongated shape on the surface of the substrate 101. The entire surface of the amorphous silicon film 175 is crystallized by scanning it with the laser beam 121 sequentially in a direction perpendicular to the elongation of the area of the surface of the substrate 101 illuminated by the laser 121. Preferably, scanning with the laser beam 121 is performed such that some portions of two consecutive illuminated areas lie over each other at a given moment. Thus, any given point on the amorphous silicon film 175 is illuminated with a laser multiple times. As a result, the homogeneity of crystal conditions of the polycrystalline silicon film 176 is improved. When illuminated with the laser beam 121, the amorphous silicon film 175 melts for a moment and then solidifies, during which process the film is crystallized to become a polycrystalline silicon film 176. Asperities caused by ridges developed during the melting/solidification process are formed on the surface of the polycrystalline silicon film 176.

Preferably, thermal treatment is performed to dehydrogenate the amorphous silicon film 175 before it is illuminated with the laser beam 121.

Next, the polycrystalline silicon film 176 is photolithographically patterned. Specifically, a pattern of a desired polycrystalline silicon layer 171 is formed on the upper surface of the polycrystalline silicon film 176 using a resist. Then, the unnecessary portions of the polycrystalline silicon film 176 are removed using dry etching. The portion of the polycrystalline silicon film 176 where a thin film diode 130 is to be formed later is left out. The portions of the polycrystalline silicon film 176 outside the area for the thin film diode 130, including the area(s) where a thin film transistor 150 is to be formed later, are removed. As a result, as shown in FIG. 3D, a patterned polycrystalline silicon layer 171 is provided.

Next, as shown in FIG. 3E, a base layer 103 and an amorphous semiconductor film 110 are formed in this order to cover the substrate 101 and the polycrystalline silicon layer 171.

The base layer 103 may be made of a simple layer made of silicon oxide (SiO₂), for example. Known compositions other than silicon oxide (SiO₂) may also be used. The base layer 103 may be formed using plasma CVD, for example. The thickness of the base layer 103 is preferably in the range of about 50 to 100 nanometers.

Preferable semiconductors that may constitute the amorphous semiconductor film 110 include silicon. Other semiconductors, such as Ge, SiGe, compound semiconductors, or chalcogenide may also be used. The following description uses silicon. The amorphous silicon film 110 is formed using known techniques, such as plasma CVD or sputtering. The thickness of the amorphous silicon film 110 is not limited to a particular value; however, it is preferably in the range of 50 to 100 nanometers. For example, an amorphous silicon film 110 with a thickness of 50 nanometers may be formed using plasma CVD. If the base layer 103 and the amorphous silicon film 110 are formed using the same film-formation method, these two layers may be formed consecutively. In this case, surface contamination of the base layer 103 is prevented, as the base layer 103 is not exposed to the atmosphere after it is formed. As a result, variations in properties or variations in threshold voltage of the fabricated thin film transistor 150 and the thin film diode 130 are reduced.

As shown in FIG. 3E, in the area where the polycrystalline silicon layer 171 was formed, asperities similar to those on the upper surface of the polycrystalline silicon layer 171 are formed on the upper surface of the base layer 103 and the upper surface of the amorphous silicon film 110.

Next, as shown in FIG. 3F, the amorphous silicon film 110 is crystallized by illuminating the amorphous silicon film 110 with a laser beam 122 from above. The laser beam 122 may be an XeCl excimer laser beam (with a wavelength of 308 nanometers and a pulse width of 40 nanoseconds) or a KrF excimer laser beam (with a wavelength of 248 nanometers). The laser beam 122 is adjusted to illuminate an area of an elongated shape on the surface of the substrate 101. The entire surface of the amorphous silicon film 110 is crystallized by scanning it with the laser beam 122 sequentially in a direction perpendicular to the elongation of the area of the surface of the substrate 101 illuminated by the laser 122. Preferably, scanning with the laser beam 122 is performed such that some portions of two consecutive illuminated areas lie over each other at a given moment. Thus, any given point on the amorphous silicon film 110 is illuminated with a laser multiple times. As a result, the homogeneity of crystal conditions of the polycrystalline silicon film 111 is improved. When illuminated with the laser beam 122, the amorphous silicon film 110 melts for a moment and then solidifies, during which process the film is crystallized to become a polycrystalline silicon film 111. Asperities caused by ridges developed during the melting/solidification process are formed on the surface of the polycrystalline silicon film 111. In the area where the polycrystalline silicon layer 171 was formed, the asperities that have been formed on the upper surface of the amorphous silicon film 110, caused by the asperities on the upper surface of the polycrystalline silicon layer 171, are superimposed with the asperities caused by ridges developed during the crystallization process which changes the amorphous silicon film 110 into the polycrystalline silicon film 111. Accordingly, the surface roughness of the upper surface of the semiconductor layer 131 may be made larger, in a simple manner, than the surface roughness of the upper surface of the polycrystalline silicon layer 171 or the lower surface of the polycrystalline silicon film 111 (i.e. the upper surface of the base layer 103).

Preferably, thermal treatment is performed to dehydrogenate the amorphous silicon film 110 before it is illuminated with the laser beam 122.

Preferably, any natural oxide of the amorphous silicon film 110 is removed before the film is illuminated with the laser beam 122. Thus, the surface roughness of the polycrystalline silicon film 111 is reduced in the areas where no polycrystalline silicon layer 171 is formed. Preferably, illumination with the laser beam 122 is performed in an inert atmosphere, such as nitrogen, because this further reduces the surface roughness of the polycrystalline silicon film 111 in the areas where no polycrystalline silicon layer 171 is formed.

Next, as shown in FIG. 3G, the unnecessary portions of the polycrystalline silicon film 111 are removed to separate the devices from each other. The devices may be separated from each other using photolithography, that is, by removing the unnecessary portions of the polycrystalline silicon film 111 using wet etching after a resist of a predetermined pattern is formed. Thus, the semiconductor layer 131 which is to be an active region (i.e. an n-type region 131n, a p-type region 131p and an intrinsic region 131i) of a thin film diode 130 later and the semiconductor layer 151 which is to be an active region (i.e. a source region 151a, a drain region 151b and a channel region 151c) of a thin film transistor 150 later are formed separate from each other. Thus, these semiconductor layers 131 and 151 are formed like islands.

Next, as shown in FIG. 3H, after a gate insulating film 105 covering these island-like semiconductor layers 131 and 151 are formed, a gate electrode 152 of the thin film transistor 150 is formed on the gate insulating film 105.

Preferably, the gate insulating film 105 is a silicon oxide film. The thickness of the gate insulating film 105 is preferably in the range of 20 to 150 nanometers (for example, 100 nanometers). As shown in FIG. 3H, in the area where the semiconductor layer 131 was formed, asperities similar to those on the upper surface of the semiconductor layer 131 are formed on the upper surface of the gate insulating film 105. In the area where the semiconductor layer 151 was formed, asperities similar to those on the upper surface of the semiconductor layer 151 are formed on the upper surface of the gate insulating film 105.

The gate electrode 152 is formed by depositing a conductive film over the gate insulating film 105 using sputtering or CVD and patterning this conductive film. It is desirable that the conductive film be made of a high-melting-point metal such as W, Ta, Ti, Mo or an alloy thereof. Further, the thickness of the conductive film is preferably in the range of 300 to 600 nanometers.

Next, as shown in FIG. 3I, a mask 122 made of a resist is formed on the gate insulating film 105, covering an area including the portion of the semiconductor layer 131 that is to be an active region of the thin film diode 130 later. Then, the entire surface of the substrate 101 is ion-doped with n-type impurities (such as phosphorus) 123 from above the substrate 101. The n-type impurities 123 pass through the gate insulating film 105 and are injected into the semiconductor layers 151 and 131. This step injects n-type impurities 123 into the regions of the semiconductor layer 131 of the thin film diode 130 not covered with the mask 122 and the regions of the semiconductor layer 151 of the thin film transistor 150 not covered with the gate electrode 152. The regions covered with the mask 122 or the gate electrode 152 are not doped with n-type impurities 123. Thus, the region of the semiconductor layer 131 of the thin film diode 130 into which n-type impurities 123 are injected is to be the n-type region 131n of the thin film diode 130 later. The regions of the semiconductor layer 151 of the thin film transistor 150 into which n-type impurities 123 are injected are to become the source region 151a and the drain region 151b of the thin film transistor 150 later. The region of the semiconductor layer 151 that is covered with the gate electrode 152 and into which no n-type impurities 123 are injected is to become the channel region 151c of the thin film transistor 150 later.

Next, after the mask 122 is removed, as shown in FIG. 3J, a mask 124 made of a resist is formed on the gate insulating film 105, covering an area including the portion of the semiconductor layer 131 that is to be an active region of the thin film diode 130 later, and the entire semiconductor layer 151, which is to be an active region of the thin film transistor 150 later. Then, the entire surface of the substrate 101 is ion-doped with p-type impurities (such as boron) 125 from above the substrate 101. The p-type impurities 125 pass through the gate insulating film 105 and are injected into the semiconductor layer 131. This step injects p-type impurities 125 into the region of the semiconductor layer 131 of the thin film diode 130 not covered with the mask 124. The regions covered with the mask 124 are not doped with p-type impurities 125. Thus, the region of the semiconductor layer 131 of the thin film diode 130 into which p-type impurities 125 are injected is to become the p-type region 131p of the thin film diode 130 later. Further, the regions of the semiconductor layer 131 into which no p-type impurities and no n-type impurities are injected are to become the intrinsic region 131i later.

Next, as shown in FIG. 3K, after the mask 124 is removed, thermal treatment is performed in an inert atmosphere, such as a nitrogen atmosphere. This thermal treatment removes doping damage, such as crystal deficiencies produced during doping, in the n-type region 131n and the p-type region 131p of the thin film diode 130, as well as in the source region 151a and the drain region 151b of the thin film transistor 150, and phosphorus and boron injected therein are activated. This thermal treatment may be performed using a typical heating furnace; however, it is preferably performed using RTA (rapid thermal annealing). Methods in which hot inert gases are blown onto the surface of the substrate 101 and temperature is rapidly increased and decreased are particularly suitable.

Next, as shown in FIG. 3L, an interlayer insulating film 107 is formed. The interlayer insulating film 107 is not limited to a particular structure, and any known compositions may be used. For example, a double structure in which a silicon nitride film and a silicon oxide film are formed in this order may be used. Thermal treatment for hydrogenating the semiconductor layers 151 and 131, such as annealing at 350 to 450° C. in a nitrogen atmosphere or hydrogen mixture atmosphere at 1 atmosphere, for example, may be performed where necessary. After the interlayer insulating film 107 is formed, contact holes are formed in the interlayer insulating film 107. Next, a film made of a metal material (for example, a double film of titanium nitride and aluminum) is formed on the interlayer insulating film 107 and inside the contact holes, and the film is patterned. Thus, electrodes 133a and 133b of the thin film diode 130 and electrodes 153a and 153b of the thin film transistor 150 are formed. Thus, a thin film diode 130 connected with the electrodes 133a and 133b and a thin film transistor 150 connected with the electrodes 153a and 153b are provided. A planarizing film made of, for example, a silicon nitride film (see the planarizing film 108 in FIGS. 5, 6, 9, and 10 discussed below) may be provided on the interlayer insulating film 107 in order to protect the electrodes 133a and 133b connected with the thin film diode 130 and the electrodes 153a and 153b connected with the thin film transistor 150, and to provide a flat surface.

According to the above method, the semiconductor layer 131 of the thin film diode 130 and the semiconductor layer 151 of the thin film transistor 150 may be formed concurrently. Thus, a thin film diode 130 and a thin film transistor 150 may be fabricated efficiently on a common substrate 101.

This manufacturing method necessarily produces a semiconductor layer 131 of a thin film diode 130 with a thickness equal to that of the semiconductor layer 151 of the thin film transistor 150. As such, the thickness of the semiconductor layer 131 of the thin film diode 130 cannot be increased to improve light detection sensitivity. However, as discussed above, in a semiconductor device 100A according to an embodiment of the present invention, the light detection sensitivity of the light sensor 132 (thin film diode 130) is improved even if the thickness of the semiconductor layer 131 cannot be increased.

Further, according to the above manufacturing method, forming a polycrystalline silicon layer 171 with asperities formed on its upper surface causes the lower surface of the semiconductor layer 131 of the thin film diode 130 formed thereafter to have asperities similar to those on the upper surface of the polycrystalline silicon layer 171. Moreover, the upper surface of the semiconductor layer 131 may have asperities different from those on its lower surface.

Thus, according to the above manufacturing method, a semiconductor device 100A may be fabricated in a simple manner and at low cost without significantly altering the conventional manufacturing process of semiconductor devices.

As shown in FIG. 3D, the portions of the polycrystalline silicon film 176 where a thin film transistor 150 is to be formed are removed, such that the lower surface of the semiconductor layer 151 constituting the thin film transistor 150 is substantially flat (see FIG. 3G). Thus, the light detection sensitivity of the thin film diode 130 is improved without adversely affecting properties (for example, decreasing the gate capability) of the thin film transistor 150.

The thin film transistor 150 is not limited to the structure described above. For example, a dual-gate thin film transistor, an LDD or GOLD thin film transistor, a p-channel thin film transistor or the like may be used. Moreover, several types of thin film transistors with different structures may be combined.

The above embodiment has illustrated a semiconductor device 100A including a photosensor 132 and a thin film transistor 150. However, the present invention is not limited thereto. For example, only a photosensor 132 may be made. It should be noted that the light-blocking layer 160 is not a required component for the photosensor of the present invention. Further, the silicon layer of the photosensor of the present invention does not have to be implemented by the polycrystalline silicon layer 171 made of polycrystalline silicon. A silicon layer made of amorphous silicon may also be employed.

### Embodiment 2

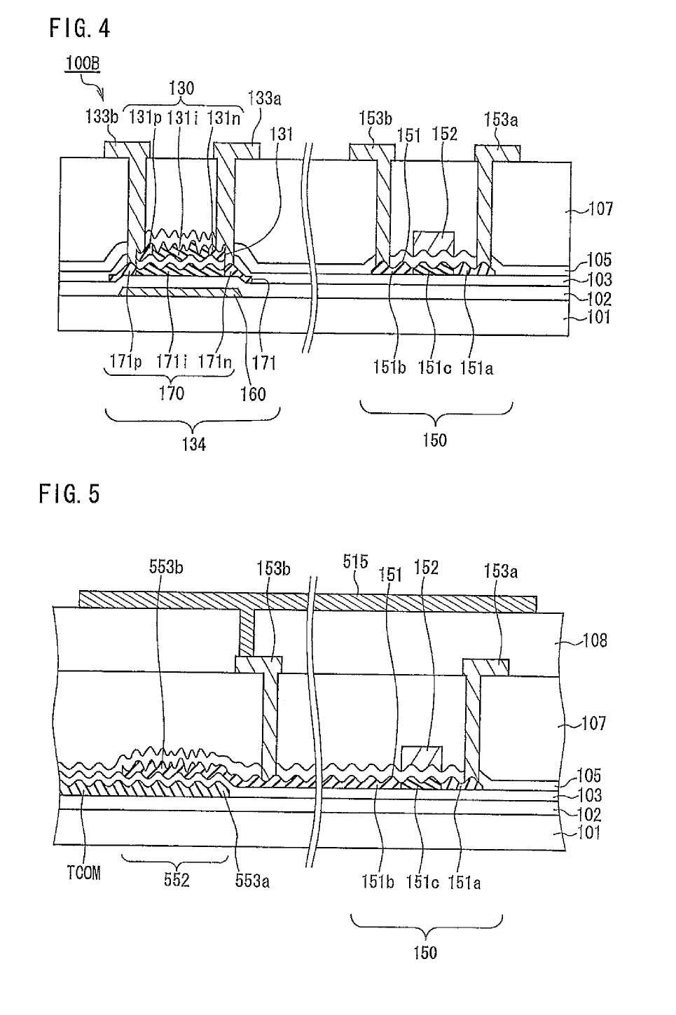

FIG. 4 is a schematic cross sectional view of a semiconductor device 100B according to Embodiment 2 of the present invention. In FIG. 4, the same components and locations as in the semiconductor device 100A of Embodiment 1 are labeled with the same numerals and their description will be omitted. A semiconductor device 100B of Embodiment 2 will now be described focusing on the differences between Embodiments 1 and 2.

In Embodiment 2, an n-type region 171n and a p-type region 171p are formed in the polycrystalline silicon layer 171, and an electrodes 133a and 133b are electrically connected with the n-type region 171n and the p-type region 171p, respectively. An intrinsic region 171i is provided between the n-type region 171n and the p-type region 171p.

In such a structure, the polycrystalline silicon layer 171 may function as a second thin film diode 170. Accordingly, a photosensor 134 including a double-structure thin film diode having a first thin film diode 130 and a second thin film diode 170 is provided. As a result, for example, the second thin film diode 170 is capable of detecting light that has passed through the semiconductor layer 131 and is traveling toward the light-blocking layer 160 or light that has been reflected from the light-blocking layer 160 and is traveling toward the semiconductor layer 131. Thus, in Embodiment 2, the area occupied by the thin film diodes on the substrate is substantially the same as in Embodiment 1, and still a density of thin film diodes about twice that of Embodiment 1 is provided. As a result, light detection sensitivity is further improved. For example, as will be discussed in the context of Embodiment 5 below, if the thin film diodes 130 and 170 of the semiconductor device 100B of Embodiment 2 are shared by a plurality of switching devices (thin film transistors 150) in the pixel region of the liquid crystal panel, the total light-receiving area of thin film diodes is almost doubled, at 130 and 170, without altering the aperture ratio of the pixels. As a result, touch sensor functionality with improved detection sensitivity is realized in a liquid crystal panel.

To form an n-type region 171n, a p-type region 171p and an intrinsic region 171i in a polycrystalline silicon layer 171, a base layer 103 may be formed, for example, and then photolithography may be performed, similar to that for forming an n-type region 131n, a p-type region 131p and an intrinsic region 131i in a semiconductor layer 131. Specifically, a mask with a predetermined pattern is formed of a resist, and the polycrystalline silicon layer 171 may be doped with n-type and p-type impurities via the base layer 103.

Further, to connect electrodes 133a and 133b with the n-type region 171n and the p-type region 171p, respectively, contact holes for forming the electrodes 133a and 133b may be formed to reach the n-type region 171n and the p-type region 171p.

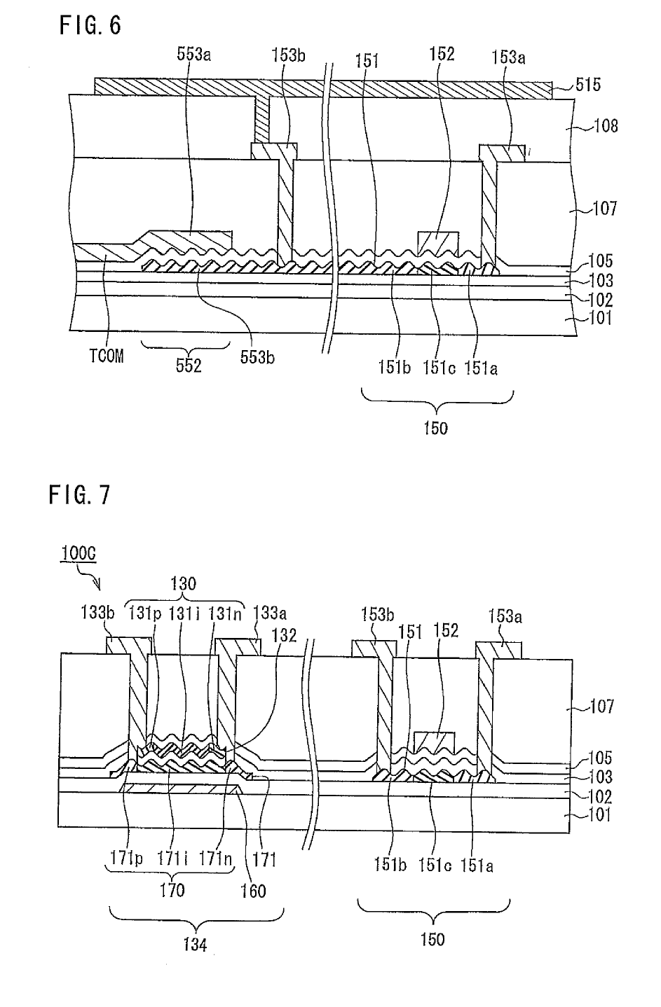

As discussed above, Embodiment 2 requires the step of doping the polycrystalline silicon layer 171 with impurities. Accordingly, for example, concurrently with the formation of the polycrystalline silicon layer 171 (see FIG. 3D), a separate patterned polycrystalline silicon film may be formed and, concurrently with the doping of the polycrystalline silicon layer 171 with impurities, this separate polycrystalline silicon film may be doped to have a lower resistance such that the separate polycrystalline silicon film, with a lower resistance, may be used as lines and electrodes. A cross section of a TFT array substrate of a liquid crystal panel including such lines and electrodes is shown in FIG. 5. For comparison, FIG. 6 shows a cross section of a TFT array substrate of a liquid crystal panel that does not include such lines. In FIGS. 5 and 6, the parts and locations similar to those shown in FIG. 4 are labeled with the same numerals. The numeral 108 indicates a planarizing film formed on the interlayer insulating film 107.

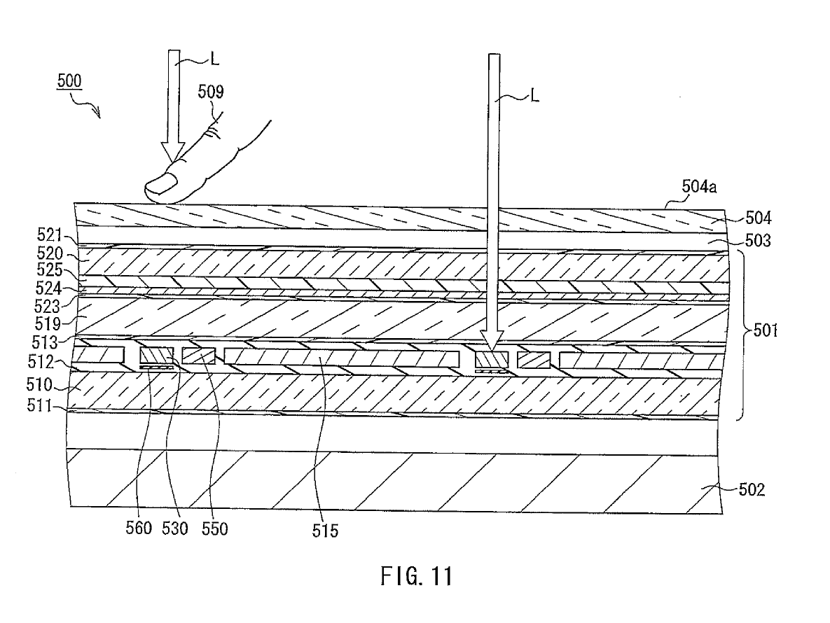

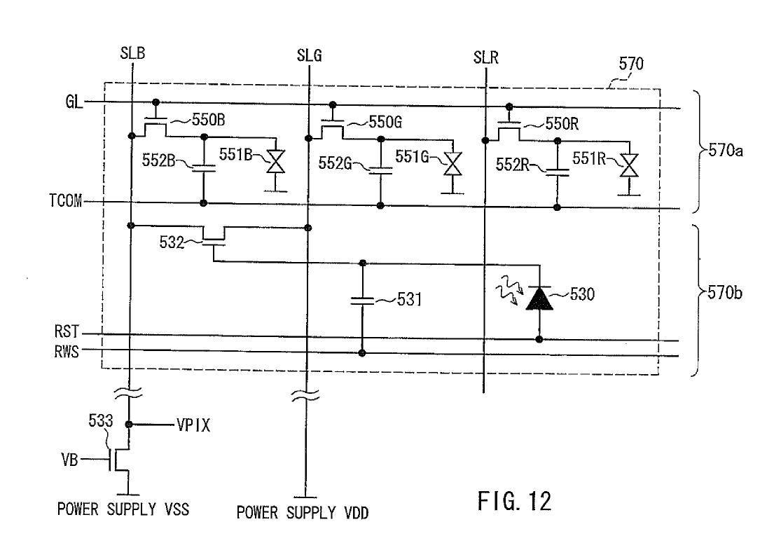

In each of the TFT array substrates shown in FIGS. 5 and 6, as will be discussed in connection with Embodiment 5 below, the thin film transistor 150 constituting part of the semiconductor device 100B of Embodiment 2 is used for driving liquid crystal (the thin film transistors 550R, 550G and 550B in FIG. 12). In this case, the drain region 151b of the thin film transistor 150 is connected with one electrode 553b of the electrostatic capacitance 552 provided to stabilize a voltage applied to the liquid crystal layer 519 (see FIG. 11), and is connected, via the electrode 153b, with the pixel electrode 515 (see FIG. 11) formed on the planarizing film 108 for working together with the common electrode 524 (see FIG. 11) provided on the counter substrate 520 (see FIG. 11) to apply a voltage to the liquid crystal layer 519. The lines connecting the electrode 553b with the drain region 151b, as well as the electrode 553b itself, are made of a semiconductor doped with n-type impurities, similar to the drain region 151b. In FIG. 5, the other electrode 553a of the electrostatic capacitance 552 and the common electrode line TCOM (see FIG. 12) connected therewith are made of polycrystalline silicon formed on the base layer 102 and doped with n-type impurities (or p-type impurities), while in FIG. 6, they are made of a metal material (for example, W, Ta, Ti, Mo or an alloy thereof) that is formed on the gate insulating film 105 concurrently with the gate electrode 152, as is conventional, and that is the same as the metal material of the gate electrode 152.

In FIG. 6, the electrode 553a and the common electrode line TCOM are made of a metal material and thus light cannot pass through them.

On the other hand, in FIG. 5, the electrode 553a and the common electrode line TCOM are made of a translucent polycrystalline silicon. Thus, the pixel aperture ratio of the liquid crystal panel is significantly improved.

The electrode 553a and the common electrode line TCOM of FIG. 5 may be formed by forming a polycrystalline silicon film in a predetermined pattern on the base layer 102 concurrently with the formation of the polycrystalline silicon layer 171, and doping the polycrystalline silicon film with n-type impurities (or p-type impurities) concurrently with the doping of the polycrystalline silicon layer 171 with n-type impurities (or p-type impurities). Thus, no additional step is required to form the TFT array substrate of FIG. 5.

In FIG. 5, the electrode 553a and the common electrode line TCOM are formed of a polycrystalline silicon film doped with n-type impurities (or p-type impurities). However, in addition to the electrode 553a and the common electrode line TCOM, or instead of the electrode 553a and the common electrode line TCOM, other lines or electrodes may be formed of a polycrystalline silicon film doped with n-type impurities (or p-type impurities).

Otherwise, Embodiment 2 is similar to Embodiment 1.

### Embodiment 3

FIG. 7 is a schematic cross sectional view of a semiconductor device 100C according to Embodiment 3 of the present invention. In FIG. 7, the same components and locations as in the semiconductor device 100B of Embodiment 2 are labeled with the same numerals and their description will be omitted. A semiconductor device 100C of Embodiment 3 will now be described focusing on the differences between Embodiments 2 and 3.

In Embodiment 3, a semiconductor layer (first semiconductor layer) 132 constituting the thin film diode 130 is made of amorphous silicon and thus it is different from the semiconductor layer 131 of Embodiment 2 made of a polycrystalline semiconductor (polycrystalline silicon). The semiconductor layer 132 made of amorphous silicon includes an n-type region 131n and a p-type region 131p as well as an intrinsic region 131i between the n-type region 131n and the p-type region 131p.

The semiconductor device 100C including a semiconductor layer 132 made of amorphous silicon may be fabricated in a manner similar to that for the semiconductor device 100B of Embodiment 2 except that the step of directing a laser beam 122 to the amorphous silicon film 110 and crystallize it (see FIG. 3F) and the pretreatment accompanying this step (for example, dehydrogenation) are omitted.

Since the step of crystallizing the amorphous silicon film 110 is omitted, ridges formed during crystallization are not formed in the present embodiment. Accordingly, asperities similar to those on the upper surface of the polycrystalline silicon layer 171 are formed on the upper surface of the semiconductor layer 132.

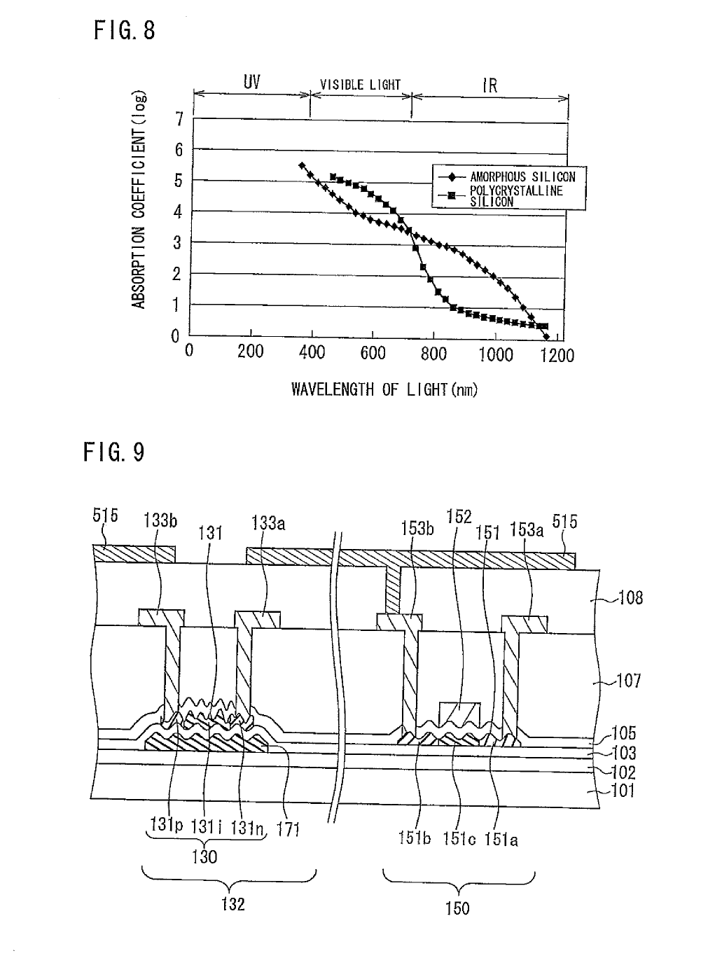

As shown in FIG. 8, polycrystalline silicon and amorphous silicon vary in light absorption coefficient depending on the wavelength in different manners. By forming the upper thin film diode 130 using amorphous silicon and forming the lower thin film diode 170 using polycrystalline silicon, as in Embodiment 3, the variations in light absorption coefficient of the semiconductor layers 132 and 171 of the thin film diodes 130 and 170 are different and thus complementary, which is not the case with Embodiment 2. This leads to smaller variations in sensitivity in the visible light range (400 to 700 nanometers) and the infrared range. As a result, light detection sensitivity is improved irrespective of the light wavelength. In other words, light detection sensitivity is improved across a wide wavelength range from the visible light to infrared ranges.

Otherwise, Embodiment 3 is similar to Embodiment 2.

It should be noted that, while FIG. 7 shows an implementation where a semiconductor layer 132 made of amorphous silicon replaces the semiconductor layer 131 made of polycrystalline semiconductor of Embodiment 2, a semiconductor layer 132 made of amorphous silicon may replace the semiconductor layer 131 made of polycrystalline semiconductor of Embodiment 1. Although, in this case, complementation in light absorption coefficient as discussed above is not achieved, improvement in light detection sensitivity as illustrated in Embodiment 1 is achieved. Also, the wavelength range where detection is facilitated can be changed. In addition, in Embodiment 2, a silicon layer made of amorphous silicon may replace the polycrystalline silicon layer 171. In this case, complementation in light absorption coefficient as discussed above is achieved.

### Embodiment 4

In the semiconductor devices 100A to 100C of Embodiments 1 to 3 each have a light-blocking layer 160 between the substrate 101 and a polycrystalline silicon layer 171. However, the light-blocking layer 160 is not required in the present invention. The light-blocking layer 160 may be omitted in some applications of the semiconductor device. For example, in a totally reflective liquid crystal display device, a reflective plate is disposed on the side of the TFT array substrate opposite the liquid crystal layer. Accordingly, no light-blocking layer is required if the semiconductor device of the present invention is used on a TFT array substrate of a totally reflective liquid crystal display device.

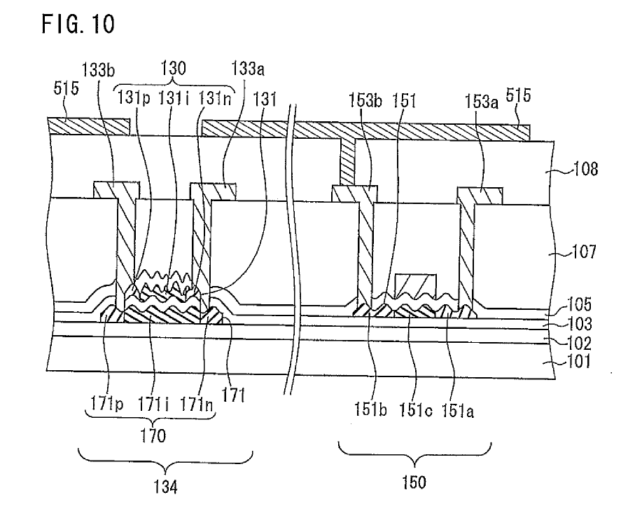

FIG. 9 is a cross sectional view of a TFT array substrate of a liquid crystal panel in a totally reflective liquid crystal display device including a semiconductor device 100A as in Embodiment 1 with no light-blocking layer 160. FIG. 10 is a cross sectional view of a TFT array substrate of a liquid crystal panel in a totally reflective liquid crystal display device including a semiconductor device 100B as in Embodiment 2 with no light-blocking layer 160. In FIGS. 9 and 10, the same components and locations as in the semiconductor devices 100A and 100B of Embodiments 1 and 2 are labeled with the same numerals and their description will be omitted. In FIGS. 9 and 10, a reflective plate (not shown) is disposed on the side of the substrate 101 opposite the side with the thin film diode 130 and the thin film transistor 150 (i.e. the lower side of the substrate 101). Light that entered a pixel electrode 515 and passed the semiconductor layer 131 and the polycrystalline silicon layer 171 is reflected from the reflective plate disposed on the lower side of the substrate 101 and re-enters the polycrystalline silicon layer 171 and the semiconductor layer 131. Thus, the reflective plate disposed on the lower side of the substrate 101 reflects light, similar to the light-blocking layer 160. Therefore, the effects of the present invention described above will be achieved without a light-blocking layer 160.

Although not shown, a semiconductor device 100C as in Embodiment 3 with no light-blocking layer 160 may be used in a TFT array substrate of a liquid crystal panel of a totally reflective liquid crystal display device.

Embodiment 4 has illustrated an implementation where the semiconductor device of the present invention without a light-blocking layer 160 is used in a TFT array substrate of a liquid crystal panel of a totally reflective liquid crystal display device; however, of course, the semiconductor device of the present invention without a light-blocking layer 160 may be used for other applications, as well.

### Embodiment 5

Embodiment 5 illustrates a liquid crystal panel including a semiconductor device having light detection functionality illustrated in Embodiments 1 to 4.

FIG. 11 is a schematic cross sectional view of a liquid crystal display device 500 including a liquid crystal panel 501 according to Embodiment 5.

The liquid crystal display device 500 includes a liquid crystal panel 501, an illuminating device 502 that illuminates the backside of the liquid crystal panel 501, and a translucent protection panel 504 disposed above the liquid crystal panel 501 with an air gap 503 interposed therebetween.

The liquid crystal panel 501 includes a TFT array substrate 510 and a counter substrate 520, both of which are translucent plates, and a liquid crystal layer 519 enclosed between the TFT array substrate 510 and the counter substrate 520. The TFT array substrate 510 and the counter substrate 520 are not limited to any particular material, and the same materials that are used in conventionally known liquid crystal panels, such as glass or an acrylic resin, may be used.

A polarizer 511 that passes or absorbs specific polarization components is provided on the side of the TFT array substrate 510 facing the illuminating device 502. An insulating layer 512 and an oriented film 513 are deposited in this order on the side of the TFT array substrate 510 opposite the polarizer 511. The oriented film 513 is a layer in which liquid crystals are oriented, and is formed of an organic film such as polyimide. Inside the insulating layer 512 are formed: a pixel electrode 515 formed of a transparent and conductive film, such as ITO; a thin film transistor (TFT) 550 connected with the pixel electrode 515 for working as a switching device for driving liquid crystal; and a thin film diode 530 having light detection functionality. A light-blocking layer 560 is formed on the side of the thin film diode 530 facing the illuminating device 502.

A polarizer 521 that passes or absorbs specific polarization components is provided on the side of the counter substrate 520 opposite the liquid crystal layer 519. On the side of the counter substrate 520 facing the liquid crystal layer 519 are formed, starting from the liquid crystal layer 519, an oriented film 523, a common electrode 524 and a color filter 525 in this order. Similar to the oriented film 513 on the TFT array substrate 510, the oriented film 523 is a layer in which liquid crystals are oriented and is formed of an organic film, such as polyimide. The common electrode 524 is formed of a transparent and conductive film, such as ITO. The color filter layer 525 includes three types of resin films (color filters) that each selectively pass light in the wavelength range of one of the primary colors: red (R), green (G) and blue (B), and a black matrix as a light-blocking layer disposed between two adjacent color filters. Preferably, no color filter or black matrix is provided in the region corresponding to a thin film diode 530.

In the liquid crystal panel 501 of the present embodiment, one pixel electrode 515 and one thin film transistor 550 are disposed for a color filter of one of the primary colors: red, green and blue, and all these together form a pixel of a primary color (subpixel). Three subpixels of red, green and blue form a color pixel (pixel). Such color pixels are arranged regularly in the vertical and horizontal directions.

The translucent protection panel 504 is made of a flat plate of glass or an acrylic resin, for example. The side of the translucent protection panel 504 opposite the liquid crystal panel 501 is a touch sensor side 504a that can be touched by a human finger 509. Disposing a translucent protection panel 504 above the liquid crystal panel 501 with an air gap 503 interposed therebetween prevents a depressing force by the human finger 509 onto the translucent protection panel 504 from being transmitted to the liquid crystal panel 501. This prevents an undesired waving pattern from being generated on the display screen by the depressing force by the finer 509.

The illuminating device 502 is not limited to a particular type and any illuminating device known as an illuminating device for a liquid crystal panel may be used. For example, a direct-lighting or edge-light illuminating device may be used. An edge-light illuminating device is preferable since it is advantageous in realizing a thin liquid crystal display device. The light source is not limited to a particular type, either, and a cold/hot-cathode tube or an LED may be used, for example.

The liquid crystal display device 500 of the present embodiment is capable of displaying a color image by permitting light from the illuminating device 502 to pass through the liquid crystal panel 501 and the translucent protection panel 504.

Meanwhile, external light, L, that entered the touch sensor side 504a enters the thin film diode 530. When the finger 509 touches the touch sensor side 504a, part of the external light L is blocked. As a change in the external light L entering a thin film diode 530 is detected, it can be determined whether the finger 509 is in contact with the touch sensor side 504a and where it is in contact with it. The light-blocking layer 560 prevents light from the illuminating device 502 from entering the thin film diode 530.

In the above arrangement, the thin film diode 530, the thin film transistor 550, the light-blocking layer 560 and the TFT array substrate 510 may be the thin film diode 130 (and the second thin film diode 170 in Embodiment 2), the thin film transistor 150, the light-blocking layer 160 and the substrate 101 illustrated in Embodiments 1 to 4. The insulating layer 512 includes the base layers 102 and 103, the gate insulating film 105, the interlayer insulating film 107 and the planarizing film 108, illustrated in Embodiments 1 to 4.

FIG. 11 shows a transmissive liquid crystal display device as the liquid crystal display device; however, the present invention is not limited thereto and may be used in a semi-transmissive or reflective liquid crystal display device. No illuminating device 502 is required in a reflective liquid crystal display device.

FIG. 12 is an equivalent circuit of one pixel of the liquid crystal panel 501 shown in FIG. 11. The pixel 570 of the liquid crystal panel 501 includes a display section 570a, constituting a color pixel, and a photosensor section 570b. A large number of such pixels 570 are arranged in a matrix in the horizontal and vertical directions in the pixel region of the liquid crystal panel 501.

The display section 570a includes thin film transistors 550R, 550G and 550B, liquid crystal elements 551R, 551G and 551B, and electrostatic capacitances 552R, 552G and 552B (the suffixes R, G and B indicate that the elements correspond to the red, green and blue subpixels constituting a pixel. The same applies to the following description). The source regions of the thin film transistors 550R, 550G and 550B are connected with the source electrode lines (signal lines) SLR, SLG and SLB, respectively. The gate electrodes are connected with the gate electrode line (scan line) GL. Each of the drain regions is connected with the pixel electrode of the respective one of the liquid crystal elements 551R, 551G and 551B (see the pixel electrode 515 of FIG. 11) and one of the electrodes of the respective one of the electrostatic capacitances 552R, 552G and 552B. The other one of the electrodes of each of the electrostatic capacitances 552R, 552G and 552B is connected with the common electrode line TCOM.

When a positive pulse is applied to the gate electrode line GL, the thin film transistors 550R, 550G and 550B are turned on. Thus, a signal voltage applied to the source electrode lines SLR, SLG and SLB is transmitted from the source electrodes of the thin film transistors 550R, 550G and 550B, respectively, via the respective drain electrodes to the liquid crystal elements 551R, 551G and 551B, respectively, and the electrostatic capacitances 552R, 552G and 552B, respectively. As a result, a voltage is applied to the liquid crystal layer 519 (see FIG. 11) by means of the pixel electrodes 515 of the liquid crystal elements 551R, 551G and 551B (see FIG. 11) and the common electrode 524 (see FIG. 11) to change the orientation of liquid crystal molecules in the liquid crystal layer 519 to achieve a desired color display.

The photosensor section 570b includes a thin film diode 530, a storage capacitance 531, and a follower thin film transistor 532. The p-type region of the thin film diode 530 is connected with the reset signal line RST. The n-type region of the thin film diode 530 is connected with one electrode of the storage capacitance 531 and the gate electrode of the follower thin film transistor 532. The other electrode of the storage capacitance 531 is connected with the read-out signal line RWS. The source electrode of the follower thin film transistor 532 is connected with the source electrode line SLG. The drain electrode of the follower thin film transistor 532 is connected with the source electrode line SLB. The source electrode line SLG is connected with a rated voltage VDD. The source electrode line SLB is connected with the drain electrode of a bias transistor 533. The source electrode of the bias transistor 533 is connected with a rated voltage VSS.

In the photosensor section 570b of this configuration, an output voltage VPIX corresponding to the amount of light received by the thin film diode 530 is obtained in the following manner.

First, a high-level reset signal is supplied to the reset signal line RST. Thus, the thin film diode 530 is forward biased. At this point, the potential of the gate electrode of the follower thin film transistor 532 is lower than the threshold voltage of the follower thin film transistor 532. Consequently, the follower thin film transistor 532 is non-conductive.

Next, the potential of the reset signal line RST is lowered to low level. Thus, an integration period of photocurrent begins. During this integration period, the amount of photocurrent proportional to the amount of light entering the thin film diode 530 flows out of the storage capacitance 531, discharging the storage capacitance 530. Even during the integration period, the potential of the gate electrode of the follower thin film transistor 532 is lower than the threshold voltage of the follower thin film transistor 532. Consequently, the follower thin film transistor 532 remains non-conductive.

Next, a high-level read-out signal is supplied to the read-out signal line RWS. Thus, the integration period ends and a read-out period begins. As a read-out signal is supplied, electric charge is accumulated in the storage capacitance 531, such that the potential of the gate electrode of the follower thin film transistor 532 becomes higher than the threshold voltage of the follower thin film transistor 532. As a result, the follower thin film transistor 532 becomes conductive and works together with the bias transistor 533 to function as a source follower amplifier. The output voltage VPIX obtained from the follower thin film transistor 532 is proportional to the value of integral of photocurrent of the thin film diode 530 during the integration period.

Next, the potential of the read-out signal line RWS is lowered to low level and the read-out period ends.

These operations are repeated for each of the pixels 570 arranged in the pixel region of the liquid crystal panel 501 to provide touch sensor functionality in the pixel region of the liquid crystal panel 501.

Using the thin film diode 130 illustrated in Embodiment 1 as the thin film diode 530 will realize a liquid crystal display device 500 having touch sensor functionality with excellent detection sensitivity.

In FIG. 12, one photosensor section 570b is provided for one display section 570a constituting a color pixel; however, the present invention is not limited to such an arrangement. For example, one photosensor section 570b may be provided for a plurality of display sections 570a. Alternatively, one photosensor section 570b may be provided for each of the subpixels for red, blue and green within one display section 570a. Further, while FIG. 12 shows an implementation where the present invention is employed in a liquid crystal panel for color display, the present invention may also be employed in a liquid crystal panel for monochrome display.

FIGS. 11 and 12 illustrate an implementation where the thin film transistor 150 of any of Embodiments 1 to 4 is the thin film transistor 550 (550R, 550G and 550B) provided in each of the subpixels; however, the present invention is not limited thereto. The thin film transistor 150 may be a thin film transistor shown in FIG. 12 other than the thin film transistors 550 (550R, 550G and 550B) provided in the subpixels. Alternatively, the thin film transistor 150 may be a thin film transistor for a driver circuit (the gate driver 510g or source driver 510s described below), for example.

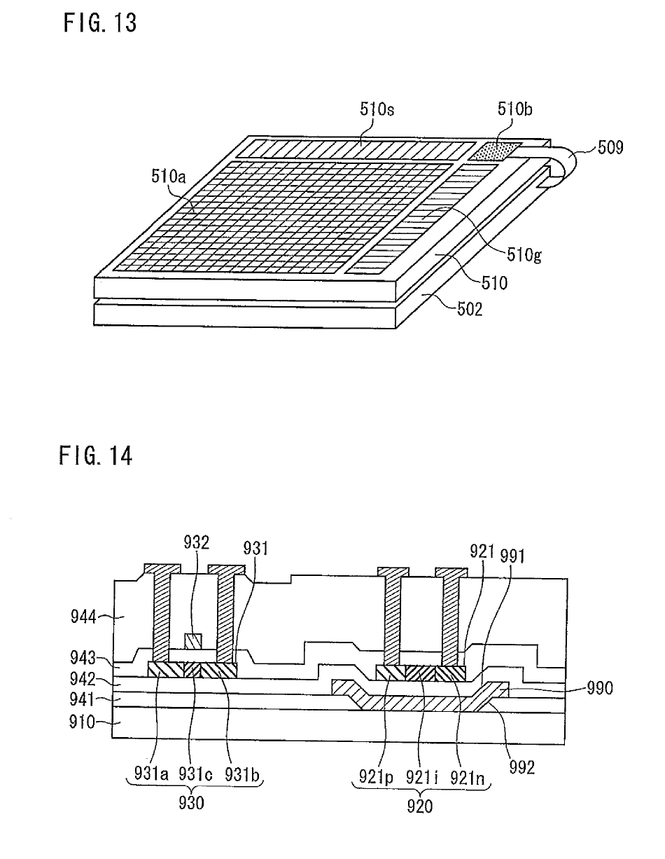

In FIGS. 11 and 12, the photosensor of the present invention having light detection functionality is provided in the pixel region of a TFT array substrate 510. However, the present invention is not limited to such an arrangement. For example, the photosensor may be provided outside the pixel region of the TFT array substrate 510. An implementation where the photosensor is provided outside the pixel region of the TFT array substrate 510 will be described referring to FIG. 13. Out of the components of a liquid crystal display device, FIG. 13 only shows the TFT array substrate 510 and the illuminating device 502 that illuminates the backside of the TFT array substrate 510. The TFT array substrate 510 includes a pixel region 510a in which a large number of thin film transistors for driving liquid crystal are arranged in a matrix, and a gate driver 510g, a source driver 510s and a light detection unit 510b are provided in a frame-shaped area around the pixel region 510a. The photosensor of the present invention is formed in the light detection unit 510b. The thin film diode in the light detection unit 510b generates an illuminance signal corresponding to the brightness of the environment of the liquid crystal display device. The illuminance signal is input to a control circuit (not shown) of the illuminating device 502 via a line 509 of a flexible substrate, for example. The control circuit controls the illuminance of the illuminating device 502 in accordance with the illuminance signal. As a result, a liquid crystal display device where the brightness of the display screen is automatically regulated in accordance with the brightness of the environment is provided. Thus, the photosensor of the present invention may be disposed in the frame-shaped area of the TFT array substrate 510 and be used as an ambient sensor that measures the brightness of the environment of the liquid crystal display device. Since the photosensor of the present invention has excellent light detection sensitivity, it provides a liquid crystal display device where the brightness of the display screen is optimized in accordance with the brightness of the environment. Further, a larger thin film diode can be provided than in an implementation where a thin film diode is formed inside the pixel region, thereby increasing the light receiving area to further improve light detection sensitivity in a simple manner.

Embodiment 5 has illustrated an implementation where the semiconductor device of the present invention illustrated in any of Embodiments 1 to 4 is used in a liquid crystal panel; however, the semiconductor device of the present invention is not limited to such an application. The semiconductor device of the invention may be used as a display element, such as an EL panel, a plasma panel or the like. Alternatively, the semiconductor device of the invention may be used in various equipment including light detection functionality other than a display element.

While the present invention is not limited to any particular application field, it may be used widely in various equipment in which a photosensor with improved light detection sensitivity is required. Particularly, it may be suitably used in various display elements as a touch sensor or an ambient sensor that measures the brightness of the environment.

1. A photosensor comprising:
a substrate;
a thin film diode provided close to one side of the substrate and having a first semiconductor layer including, at least, an n-type region and a p-type region; and
a silicon layer provided between the substrate and the first semiconductor layer,
wherein asperities are provided on a side of the silicon layer facing the first semiconductor layer, and
asperities are provided on a side of the first semiconductor layer facing the silicon layer and a side thereof opposite the side facing the silicon layer.

2. The photosensor according to claim 1, wherein:
the silicon layer is made of polycrystalline silicon; and
the asperities formed on the silicon layer include ridges formed on crystal grain boundaries of silicon.

3. The photosensor according to claim 1, wherein the side of the first semiconductor layer opposite the silicon layer side has a surface roughness that is larger than that of the side of the silicon layer facing the first semiconductor layer.

4. The photosensor according to claim 1, further comprising a light-blocking layer provided between the substrate and the silicon layer.

5. The photosensor according to claim 1, wherein at least an n-type region and a p-type region are formed in the silicon layer, the n-type region and the p-type region of the silicon layer being electrically connected with the n-type region and the p-type region, respectively, of the first semiconductor layer.

6. The photosensor according to claim 1, wherein one of the first semiconductor layer and the silicon layer is made of amorphous silicon and the other one of the first semiconductor layer and the silicon layer may be made of polycrystalline silicon.

7. A semiconductor device comprising:
the photosensor according to claim 1; and
a thin film transistor provided close to the same side of the substrate as the thin film diode,
wherein the thin film transistor includes: a second semiconductor layer including a channel region, a source region and a drain region; a gate electrode that controls a conductivity of the channel region; and a gate insulating film provided between the second semiconductor layer and the gate electrode.

8. The semiconductor device according to claim 7, wherein the first semiconductor layer and the second semiconductor layer are formed on a single insulating layer.

9. The semiconductor device according to claim 7, wherein a side of the second semiconductor layer facing the substrate is flat.

10. The semiconductor device according to claim 7, wherein the first semiconductor layer has a thickness that is identical with that of the second semiconductor layer.

11. A liquid crystal panel comprising: the semiconductor device according to claim 7; a counter substrate facing the side of the substrate where the thin film diode and the thin film transistor are provided; and a liquid crystal layer enclosed between the substrate and the counter substrate.

12. The liquid crystal panel according to claim 11, wherein:
the thin film transistor is a transistor for driving liquid crystal;
the drain region is connected with a pixel electrode that works together with a common electrode on the counter substrate to apply a voltage to the liquid crystal layer and one electrode of an electrostatic capacitance provided to stabilize the voltage applied to the liquid crystal layer;
the other electrode of the electrostatic capacitance and a line connected with the other electrode are formed in an n-type or p-type polycrystalline silicon thin film; and
the polycrystalline silicon thin film and the polycrystalline silicon layer are formed on a single base layer provided on the substrate.
